(19) United States
(12) Patent Application Publication
(10) Pub. No.: US 2005/0001286 A1
(43) Pub. Date: Jan. 6, 2005

(54) Memory device with vertical transistors and deep trench capacitors and manufacturing method thereof

(76) Inventors: Chang-Rong Wu, Banchiau (TW); Yi-Nan Chen, Taipei (TW); Tieh-Chiang Wu, IIan (TW)

Correspondence Address: QUINTERO LAW OFFICE, 1617 BROADWAY, 3RD FLOOR, SANTA MONICA, CA, 90404, US

(21) Appl. No.: 10/738,472

(22) Filed: Dec. 17, 2003

(30) Foreign Application Priority Data
Jul. 3, 2003 (TW) 92118166

(51) Int. Cl. H01L 27/108

(52) U.S. Cl. 257/532

(57) ABSTRACT

A memory device with vertical transistors and deep trench capacitors. This device includes a substrate containing at least one deep trench and a trench capacitor disposed in the bottom of the deep trench. A conducting wire is disposed on the trench capacitor. A trench top insulating layer, containing a first insulating layer and a second insulating layer surrounded by the first insulating layer, is disposed on the conducting wire. A control gate is disposed on the trench top insulating layer. A buried strap is provided in the substrate beside the conducting wire. A doping area is provided in the substrate beside the control gate. A manufacturing method for forming such memory device is also disclosed.

### BACKGROUND OF THE INVENTION

1. Field of the Invention

The invention relates to a memory device, and more particularly to a memory device with a vertical MOS and a trench capacitor and a method for fabricating the same.

2. Description of the Related Art

A conventional DRAM consists of a MOS and a capacitor, and the size of DRAM has been reduced to increase density on an integrated circuit (IC) chip. In-order to achieve minimal memory cell size, DRAM length must be reduced to decrease the lateral dimension of the memory cell.

Vertical transistors and trench capacitors have been developed to reduce memory cell size to highly integrate DRAMs.

A conventional trench top insulating layer is a single layer, such as a high density plasma oxide (HDP oxide) layer. HDP oxide layers typically have voids, and non-uniform surfaces, thus HDP oxide layers cannot adequately adhere to a trench. Therefore, gaps are formed between the trench top insulating layer and the trench, resulting in poor insulating ability, thus the trench top insulating layer is formed with a dish profile.

### SUMMARY OF THE INVENTION

The present invention is directed to a memory device with a vertical MOS and a trench capacitor and a method for fabricating the same to improve insulation.

Accordingly, the present invention provides a memory device with a vertical transistor and a trench capacitor comprising a substrate with at least one deep trench, a trench capacitor disposed in the bottom of the deep trench, a conducting wire disposed on the trench capacitor, a trench top insulating layer disposed on the conducting wire, in which the top trench insulating layer consists of a first insulating layer and a second insulating layer surrounded by the first insulating layer, and a control gate disposed on the trench top insulating layer.

The present invention also provides a method for fabricating a memory device with a vertical transistor and a trench capacitor. A substrate is provided. At least one deep trench is formed in the substrate. A trench capacitor is formed in the bottom of the deep trench. A conducting wire is formed on the trench capacitor. A trench top insulating layer is formed on the conducting wire, in which the trench top insulating layer consists of a first insulating layer and a second insulating layer surrounded by the first insulating layer. A control gate is formed on the trench top insulating layer.

The present invention provides another method for fabricating a memory device with a vertical transistor and a trench capacitor. A substrate is provided. At least one deep trench is formed in the substrate. A trench capacitor is formed in the bottom of the deep trench. An insulating layer is formed on the trench capacitor, a sidewall of the deep trench, and the substrate. Portions of the insulating layer are removed from the trench capacitor and the substrate by etching until a circular insulating layer remains on the sidewall of the deep trench. The deep trench is filled with a first conducting layer. The first conducting layer is etched to expose the circular insulating layer. The circular insulating layer is etched to below the first conducting layer in the deep trench. A second conducting layer is formed on the first conducting layer, the circular insulating layer, the sidewall of the deep trench, and the substrate. Portions of the second conducting layer are removed from the second conducting layer by etching the sidewall of the deep trench and the substrate until the remaining second conducting layer surrounds the first conducting layer and the circular insulating layer, in which a conducting wire consists of the first conducting layer and the second conducting layer. A first insulating layer is conformably formed on the second conducting layer, the sidewall of the deep trench, and the substrate. The first insulating layer is partially removed by etching the second conducting layer and the substrate to form a spacer on the sidewall of the deep trench. The deep trench is filled with a second insulating layer. The second insulating layer is etched to expose the first insulating layer. The first insulating layer is partially etched to remove the first insulating layer on the sidewall above the second insulating layer to leave the second insulating layer on a sidewall of the second insulating layer, in which a trench top insulating layer consists of the first insulating layer and the second insulating layer. A control gate is formed on the trench top insulating layer.

### BRIEF DESCRIPTION OF THE DRAWINGS

For a better understanding of the present invention, reference is made to a detailed description to be read in conjunction with the accompanying drawings, in which:

FIGS. 1 to 4 are cross-sections of the method for fabricating a memory device with a vertical MOS and a trench capacitor of the present invention.

### DETAILED DESCRIPTION OF THE INVENTION

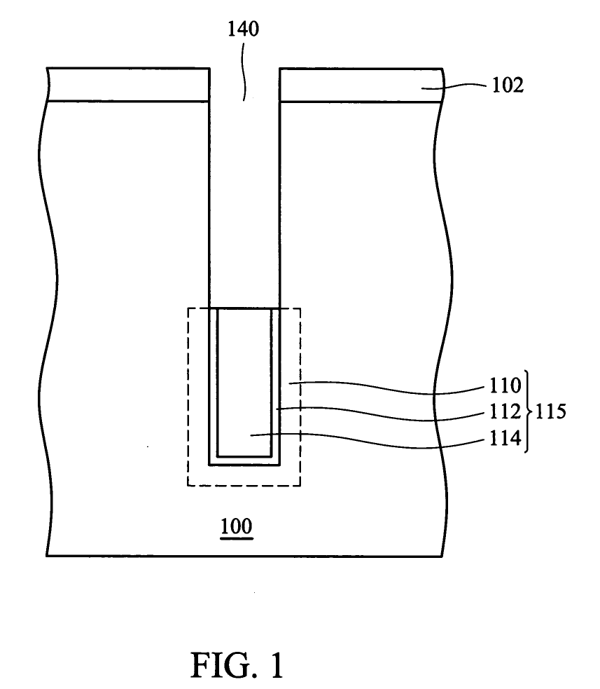

FIGS. 1 to 4 are cross-sections of the method for fabricating a memory device with a vertical transistor and a trench capacitor of an embodiment of the present invention.

In FIG. 1, a substrate 100, such as a silicon substrate, is provided. A mask layer 102 consisting of a pad oxide layer and a pad nitride layer is formed on the substrate 100, wherein a deep trench pattern is defined on the mask layer 102.

The substrate 100 is etched using the mask layer 102 as an etching mask to form a trench 104. A capacitor 115 is disposed in the bottom of the trench 104. The capacitor consists of a buried plate 110, such as N+ type doped area, a conformable capacitor dielectric layer 112, such as an oxide-nitride (ON) layer or oxide-nitride-oxide (ONO) layer, and a plate 114, such as doped poly layer. The buried plate 110 is formed in the substrate 100 of the bottom of the trench 104. A method for forming the capacitor 115 is described as follows. An N+ type dielectric layer, such as arsenic silicate glass (ASG), is formed on the trench 104. The trench 104 is filled with a photoresist layer to a predetermined depth. The N+ type dielectric layer is wet etched using the photoresist layer as an etching mask. After the photoresist layer is removed, an insulating layer, such as TEOS oxide layer, is conformably formed to prevent N+ type ion diffusion in the substrate 100 beside the trench 104 in subsequent steps. The N+ type dielectric layer is annealed to diffuse the N+ type ions into the substrate 100, forming an N+ type doped area as the buried plate 110. The insulating layer and the N+ type dielectric layer are removed. A conformable dielectric layer is formed, and the trench 104 is filled with a conducting layer. The dielectric layer and the conducting layer formed on the trench top and the substrate surface are recessed to form the capacitor dielectric layer 112 and the plate 114.

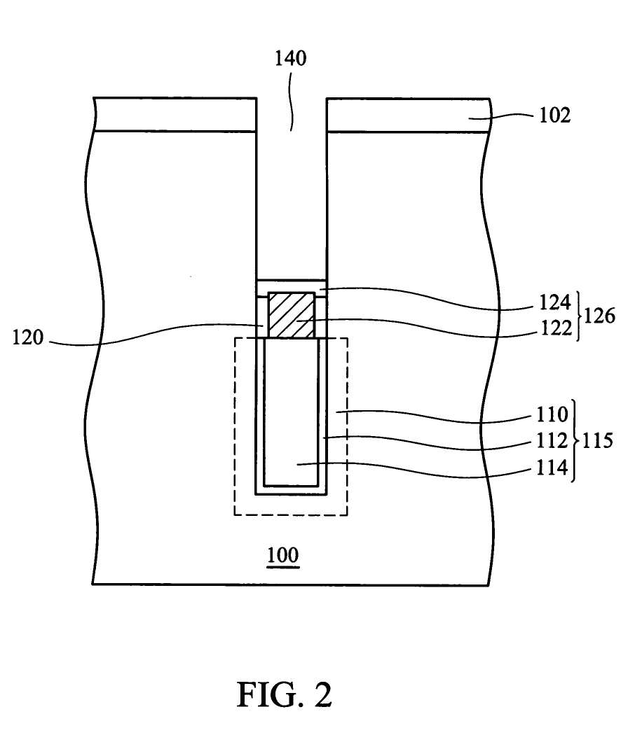

In FIG. 2, an insulating layer, such as an oxide layer, is conformably formed. The insulating layer above the mask layer 102 and the capacitor 115 is etched to form a collar insulating layer 120, isolating the substrate 100 and a conducting wire. The trench 104 is filled with a first conducting layer 122, such as doped poly layer or doped epi-silicon layer. The first conducting layer 122 and the collar insulating layer 120 are recessed respectively to a predetermined depth, thus the first conducting layer 122 is surrounded by the collar insulating layer 120, and the collar insulating layer 120 is lower than the first conducting layer 122. A second conducting layer 124, such as an undoped poly layer or undoped epi-silicon layer, is formed. The second conducting layer 124 is recessed and remains on the first conducting layer 122 and the collar insulating layer 120. In this case, a conducting wire 126 consists of the first conducting layer 122 and the second conducting layer 124.

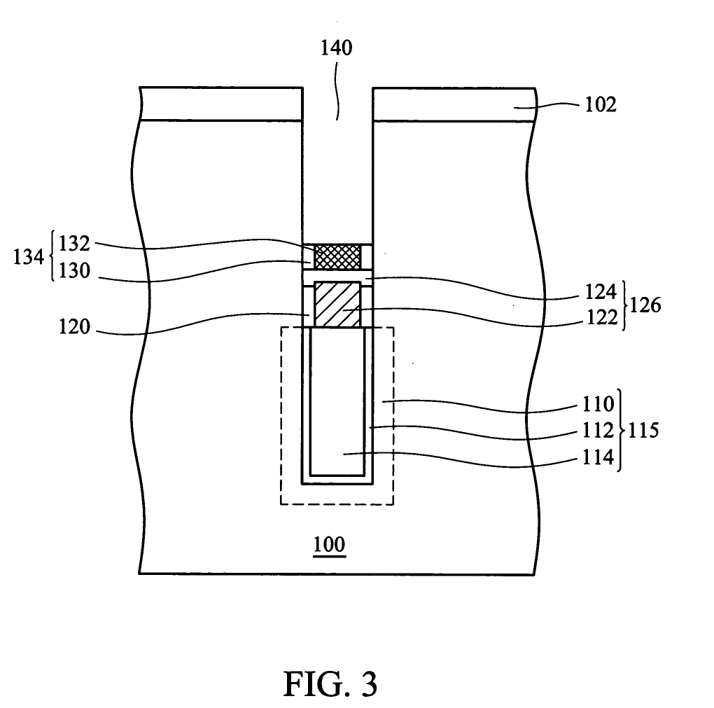

In FIG. 3, a first insulating layer 130, such as an oxide-nitride (ON) layer, is conformably formed on the second conducting layer 124, sidewall of the trench 104, and the mask layer 102. The oxide layer oxide layer of the ON layer is formed by thermal oxidation, and the thickness is 40 to 100 Å, preferably 50 Å. The nitride layer of the ON layer is formed by chemical vapor deposition (CVD), and the thickness is 1200 to 1500 Å, preferably 1300 Å. The first insulating layer 130 is anisotropically etched to form a spacer on the sidewall of the trench 104, and the first insulating layer 130 on the second conducting layer 124 and the mask layer 102 are removed. The trench 104 is filled with a second insulating layer 132, such as borophosphosilicate glass (BPSG), phosphosilicate glass (PSG), nondopedsilicate glass (NSG), or tetraethylorthosilicate (TEOS), by low pressure chemical vapor deposition (LPCVD). The second insulating layer 132 is recessed to leave a thickness of 200 to 400 Å, preferably 50 Å, and is surrounded by the first insulating layer 130. The first insulating layer 130 on the sidewall of the trench 104 above is removed from the second insulating layer 132. A trench top insulating layer 134 consisting of the first insulating layer 130 and the second insulating layer 132 is formed to isolate the conducting wire 126 and a control gate 144.

The first insulating layer 130 is formed to prevent gaps between the second insulating layer 132 and the sidewall of the trench 104. The materials and thicknesses of the first insulating layer 130 and the second insulating layer 132 are not limited to this.

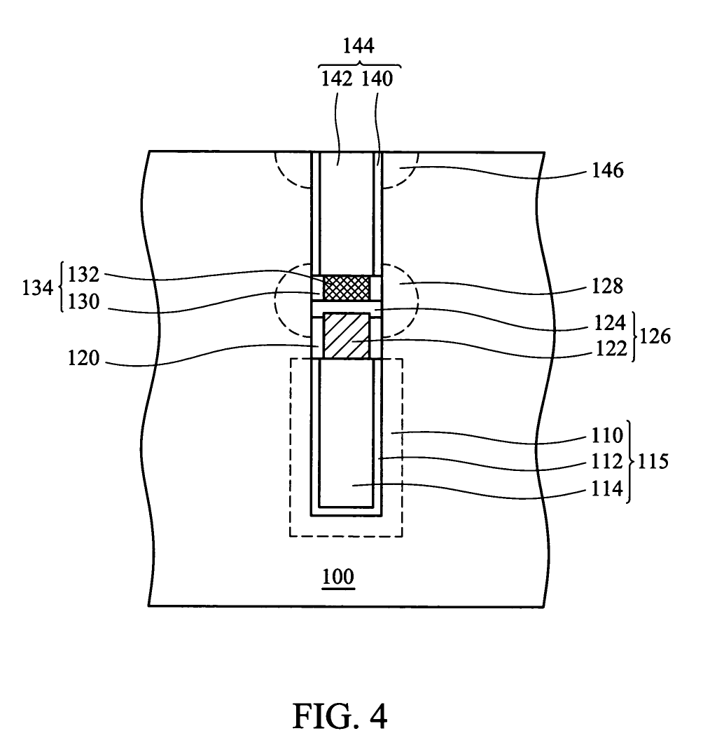

In FIG. 4, agate oxide layer 140 is formed on the sidewall of the trench 104 above the trench top insulating layer 130, and a gate conducting layer 142, such as poly layer, WSi layer, metal layer, or a composite thereof, is formed and surrounded by the gate oxide layer 140. In this case, the control gate 144 consists of the gate oxide layer 140 and the gate conducting layer 142. The substrate 100 is ion implanted to form a doped area 146 as a source beside the control gate 144. The first conducting layer 122 is annealed to diffuse ions into the substrate 100 through the second conducting layer 124, thus forming a buried strap 128. The buried strap 128 is higher than the trench top insulating layer 134, and is electrically connected to the control gate 144. In this case, the buried strap 128 is a drain.

The memory device with the vertical MOS and the trench capacitor of the present invention comprises the substrate 100 having a trench, the trench capacitor 115 formed in the bottom of the trench, the conducting wire 126 formed on the trench capacitor 115, the trench top insulating layer 134 formed on the conducting wire 126, the control gate 144 formed on the trench top insulating layer 130, the buried strap 128 formed in the substrate 100 beside the second conducting layer 124, and the doped area 146 forming in the substrate 100 beside the control gate 144. The trench capacitor 115 comprises the buried plate 110, the capacitor dielectric layer 112, and the plate 114. The collar insulating layer 120 isolates the conducting wire 126 and the substrate 100. The conducting wire 126 comprises the first conducting layer 122 formed in the region surrounded by the collar insulating layer 120, and the second conducting layer 124 forming on the first conducting layer 124 and the collar insulating layer 120. The trench top insulating layer 134 comprises the first insulating layer 130 and the second insulating layer 132. The first insulating layer 130 is the spacer surrounding the second insulating layer 132.

The present invention provides a complex trench top insulating layer consisting of the first insulating layer and the second insulating layer to replace the single trench top insulating layer of the memory cell with the vertical MOS and the trench capacitor. The first insulating layer adheres to the trench sidewall, and the second insulating layer adheres to the first insulating layer and the trench, thus the rough surface of the sidewall of the trench is improved. Therefore, there are no gaps between the trench top insulating layer and the trench.

While the invention has been described by way of example and in terms of the preferred embodiments, it is to be understood that the invention is not limited to the disclosed embodiments. To the contrary, it is intended to con various modifications and similar arrangements (as would be apparent to those skilled in the art). Therefore, the scope of the appended claims should be accorded the broadest interpretation so as to encompass all such modifications and similar arrangements.

1. A memory device with a vertical transistor and a trench capacitor, comprising:
a substrate with at least one deep trench;
a trench capacitor disposed in the bottom of the deep trench;
a conducting wire disposed on the trench capacitor;
a trench top insulating layer disposed on the conducting wire, in which the top trench insulating layer consists of a first insulating layer and a second insulating layer surrounded by the first insulating layer; and
a control gate disposed on the trench top insulating layer.

2. The memory device with a vertical transistor and a trench capacitor of claim 1, further comprising a buried strap in the substrate beside the conducting wire to electrically connect the control gate as a drain.

3. The memory device with a vertical transistor and a trench capacitor of claim 1, further comprising a doped area in the substrate beside the control gate as a source.

4. The memory device with a vertical transistor and a trench capacitor of claim 1, wherein the first insulating layer is an oxide-nitride layer.

5. The memory device with a vertical transistor and a trench capacitor of claim 4, wherein a thickness of the oxide layer is 5 to 10 Å.

6. The memory device with a vertical transistor and a trench capacitor of claim 4, wherein a thickness of the nitride layer is 40 to 50 Å.

7. The memory device with a vertical transistor and a trench capacitor of claim 4, wherein the oxide layer is formed by thermal oxidation.

8. The memory device with a vertical transistor and a trench capacitor of claim 4, wherein the nitride layer is formed by CVD.

9. The memory device with a vertical transistor and a trench capacitor of claim 1, wherein the second insulating layer is BPSG, PSG, NSG or TEOS oxide layer.

10. The memory device with a vertical transistor and a trench capacitor of claim 1, wherein a thickness of the second insulating layer is 200 to 400 Å.

11. The memory device with a vertical transistor and a trench capacitor of claim 1, wherein the second insulating layer is formed by LPCVD.

12. The memory device with a vertical transistor and a trench capacitor of claim 1, wherein the conducting wire has a first conducting layer and a second conducting layer, the conducting wire and the substrate are isolated by a circular insulating layer, and the second conducting layer surrounds the first conducting layer and the circular insulating layer.

13. The memory device with a vertical transistor and a trench capacitor of claim 12, wherein the first conducting layer is a doped poly layer or a doped epi-silicon layer.

14. The memory device with a vertical transistor and a trench capacitor of claim 12, wherein the second conducting layer is a poly layer or a epi-silicon layer.

15. The memory device with a vertical transistor and a trench capacitor of claim 12, wherein the circular insulating layer is a silicon oxide layer.

16. The memory device with a vertical transistor and a trench capacitor of claim 1, wherein the control gate consists of a gate conducting layer and a gate oxide layer, and the gate conducting layer consists of a poly layer, a WSi layer, a metal layer, or a composite thereof.

17. A method for fabricating a memory device with a vertical transistor and a trench capacitor, comprising:
providing a substrate;
forming at least one deep trench in the substrate;
forming a trench capacitor in the bottom of the deep trench;
forming a conducting wire on the trench capacitor;
forming a trench top insulating layer on the conducting wire, in which the trench top insulating layer consists of a first insulating layer and a second insulating layer surrounded by the first insulating layer; and
forming a control gate on the trench top insulating layer.

18. The method for fabricating a memory device with a vertical transistor and a trench capacitor of claim 17, further comprising a buried strap in the substrate beside the conducting wire to electrically connect the control gate as a drain.

19. The memory device with a vertical transistor and a trench capacitor of claim 17, further comprising a doped area in the substrate beside the control gate as a source.

20. The memory device with a vertical transistor and a trench capacitor of claim 17, wherein the first insulating layer is an oxide-nitride layer.

21. The memory device with a vertical transistor and a trench capacitor of claim 20, wherein a thickness of the oxide layer is 5 to 10 Å.

22. The memory device with a vertical transistor and a trench capacitor of claim 20, wherein a thickness of the nitride layer is 40 to 50 Å.

23. The memory device with a vertical transistor and a trench capacitor of claim 20, wherein the oxide layer is formed by thermal oxidation.

24. The memory device with a vertical transistor and a trench capacitor of claim 20, wherein the nitride layer is formed by CVD.

25. The memory device with a vertical transistor and a trench capacitor of claim 17, wherein the second insulating layer is BPSG, PSG, NSG or TEOS oxide layer.

26. The memory device with a vertical transistor and a trench capacitor of claim 17, wherein a thickness of the second insulating layer is 200 to 400 Å.

27. The memory device with a vertical transistor and a trench capacitor of claim 17, wherein the second insulating layer is formed by LPCVD.

28. The memory device with a vertical transistor and a trench capacitor of claim 17, wherein the conducting wire has a first conducting layer and a second conducting layer, the conducting wire and the substrate are isolated by a circular insulating layer, and the second conducting layer surrounds the first conducting layer and the circular insulating layer.

29. The memory device with a vertical transistor and a trench capacitor of claim 28, wherein the first conducting layer is a doped poly layer or a doped epi-silicon layer.

30. The memory device with a vertical transistor and a trench capacitor of claim 28, wherein the second conducting layer is a poly layer or an epi-silicon layer.

31. The memory device with a vertical transistor and a trench capacitor of claim 28, wherein the circular insulating layer is a silicon oxide layer.

32. The memory device with a vertical transistor and a trench capacitor of claim 28, wherein the control gate consists of a gate conducting layer and a gate oxide layer, and the gate conducting layer consists of a poly layer, a WSi layer, a metal layer, or a composite thereof.

33. A method for fabricating a memory device with a vertical transistor and a trench capacitor, comprising:
providing a substrate;
forming at least one deep trench in the substrate;
forming a trench capacitor in the bottom of the deep trench;
forming a insulating layer on the trench capacitor, a sidewall of the deep trench, and the substrate;
etching the insulating layer until the insulating layer on the trench capacitor and the substrate is removed to form a circular insulating layer on the sidewall of the deep trench;
filling a first conducting layer in the deep trench;
etching the first conducting layer to expose the circular insulating layer;
etching the circular insulating layer to below the first conducting layer in the deep trench;
forming a second conducting layer on the first conducting layer, the circular insulating layer, the sidewall of the deep trench, and the substrate;
partially etching the second conducting layer to remove the second conducting layer on the sidewall of the deep trench and the substrate to leave the second conducting layer coning the first conducting layer and the circular insulating layer, in which a conducting wire consists of the first conducting layer and the second conducting layer;
conformably forming a first insulating layer on the second conducting layer, the sidewall of the deep trench, and the substrate;
partially etching the first insulating layer to remove the first insulating layer on the second conducting layer and the substrate to form a spacer on the sidewall of the deep trench;
filling a second insulating layer in the deep trench;
etching the second insulating layer to expose the first insulating layer;
etching the first insulating layer to remove the first insulating layer on the sidewall above the second insulating layer to leave the second insulating layer on a sidewall of the second insulating layer, in which a trench top insulating layer consists of the first insulating layer and the second insulating layer; and
forming a control gate on the trench top insulating layer.

34. The method for fabricating a memory device with a vertical transistor and a trench capacitor of claim 33, further comprising a buried strap in the substrate beside the conducting wire to electrically connect the control gate as a drain.

35. The memory device with a vertical transistor and a trench capacitor of claim 33, further comprising a doped area in the substrate beside the control gate as a source.

36. The memory device with a vertical transistor and a trench capacitor of claim 33, wherein the first insulating layer is an oxide-nitride layer.

37. The memory device with a vertical transistor and a trench capacitor of claim 36, wherein a thickness of the oxide layer is 5 to 10 Å.

38. The memory device with a vertical transistor and a trench capacitor of claim 36, wherein a thickness of the nitride layer is 40 to 50 Å.

39. The memory device with a vertical transistor and a trench capacitor of claim 36, wherein the oxide layer is formed by thermal oxidation.

40. The memory device with a vertical transistor and a trench capacitor of claim 36, wherein the nitride layer is formed by CVD.

41. The memory device with a vertical transistor and a trench capacitor of claim 33, wherein the second insulating layer is BPSG, PSG, NSG or TEOS oxide layer.

42. The memory device with a vertical transistor and a trench capacitor of claim 33, wherein a thickness of the second insulating layer is 200 to 400 Å.

43. The memory device with a vertical transistor and a trench capacitor of claim 33, wherein the second insulating layer is formed by LPCVD.

44. The memory device with a vertical transistor and a trench capacitor of claim 33, wherein the first conducting layer is a doped poly layer or a doped epi-silicon layer.

45. The memory device with a vertical transistor and a trench capacitor of claim 33, wherein the second conducting layer is a poly layer or an epi-silicon layer.

46. The memory device with a vertical transistor and a trench capacitor of claim 33, wherein the circular insulating layer is a silicon oxide layer.

47. The memory device with a vertical transistor and a trench capacitor of claim 33, wherein the control gate consists of a gate conducting layer and a gate oxide layer, and the gate conducting layer consists of a poly layer, a WSi layer, a metal layer, or a composite thereof.
